(19) United States
(12) Patent Application Publication
(10) Pub. No.: US 2022/0028730 A1
(43) Pub. Date: Jan. 27, 2022

(54) SEMICONDUCTOR STRUCTURE AND METHOD FOR MANUFACTURING SAME

(71) Applicant: Changxin Memory Technologies, Inc., Hefei City (CN)

(72) Inventor: Chung Yen Chou, Hefei (CN)

(21) Appl. No.: 17/498,071

(22) Filed: Oct. 11, 2021

Related U.S. Application Data
(63) Continuation of application No. PCT/CN2021/098761, filed on Jun. 8, 2021.

(30) Foreign Application Priority Data
Jun. 29, 2020 (CN) 202010604806.7

(51) Int. Cl. H01L 21/762; H01L 21/3105; H01L 21/768; H01L 27/108

(52) U.S. Cl. CPC H01L 21/76229; H01L 21/31055; H01L 21/3212; H01L 27/10894; H01L 21/7681

(57) ABSTRACT

A semiconductor structure and a method for manufacturing the same are provided. The manufacturing method includes: providing a semiconductor substrate having trench isolation layers and a plurality of active areas; removing a preset thickness of the trench isolation layers to form a plurality of openings which expose the upper parts of the active areas; forming additional layers on side walls of the exposed upper parts of the active areas; and forming filling isolation layers in the openings to fill the openings, the filling isolation layers and the retained trench isolation layers together constituting first shallow trench isolation structures.

### CROSS-REFERENCE TO RELATED APPLICATIONS

This application is a continuation application of International Application No. PCT/CN2021/098761, filed on Jun. 8, 2021, which claims the priority to Chinese Patent Application No. 202010604806.7, filed on Jun. 29, 2020. The disclosures of International Application No. PCT/CN2021/098761 and Chinese Patent Application No. 202010604806.7 are hereby incorporated by reference in their entireties.

### BACKGROUND

With the continuous evolution of a dynamic random access memory (DRAM) process, the structure size of a DRAM is getting smaller and smaller. A manufacturing process of a storage node contact window is one of the key processes in the DRAM process. The performance of a storage node contact structure is affected by the key size of the top of an active area. If the size of the top of an active area is too small, when there is an overlay accuracy deviation, the storage node contact structure may be open or result in a higher resistance in the storage node contact structure. In the prior process, it is generally necessary to integrally increase the size of the active area to ensure that the size of the top of the active area is large enough. However, due to the limitation of the existing etching process, integrally increasing the size of the active area is difficult to form deeper shallow trenches and thus is difficult to obtain deeper shallow trench isolation structures, which affect the structure performance.

### SUMMARY

This disclosure relates to the technical field of semiconductor storage structures, and in particular to a semiconductor structure and a method for manufacturing the same.

According to various embodiments of this disclosure, a semiconductor structure and a method for manufacturing a semiconductor structure are provided.

The embodiments of this disclosure provide a method for manufacturing a semiconductor structure, and include the following operations.

A semiconductor substrate is provided, in which a plurality of active areas and trench isolation layers are formed.

A part of each of the trench isolation layers is removed to form a plurality of openings with a preset depth, in which the openings expose the upper parts of the active areas.

Additional layers are formed on side walls of the exposed upper parts of the active areas.

Filling isolation layers are formed in the openings to fill them, in which the filling isolation layers and the remaining trench isolation layers together constitute first shallow trench isolation structures.

The embodiments of this disclosure further provide a semiconductor structure which includes a semiconductor substrate and additional layers.

In the semiconductor substrate, a plurality of first shallow trench isolation structures and a plurality of active areas are provided.

The additional layers coat side walls of upper parts of the active areas.

### BRIEF DESCRIPTION OF THE DRAWINGS

In order to more clearly illustrate the technical solutions in the embodiments of this disclosure or in the traditional technology, the drawings required for description in the embodiments or the traditional technology will be briefly described below. It is apparent that the drawings in the following description are only some embodiments of this disclosure. Those skilled in the art can also obtain other drawings according to these drawings without any creative work.

FIG. 1 is a flowchart of a manufacturing method of a semiconductor structure provided by the embodiments of this disclosure.

FIGS. 2-12 are schematic structural views of a semiconductor structure provided by the embodiments of this disclosure after gradual etching.

### DETAILED DESCRIPTION

In order to make the foregoing objectives, features and advantages of this disclosure more obvious and understandable, the specific implementation modes of this disclosure are described in detail with reference to the accompanying drawings. Many specific details are described in the following descriptions to facilitate full understanding of this disclosure. However, this disclosure can be implemented in a variety of other ways than those described herein, and those skilled in the art can make similar improvements without departing from the connotation of this disclosure. Therefore, this disclosure is not limited by specific implementations disclosed below.

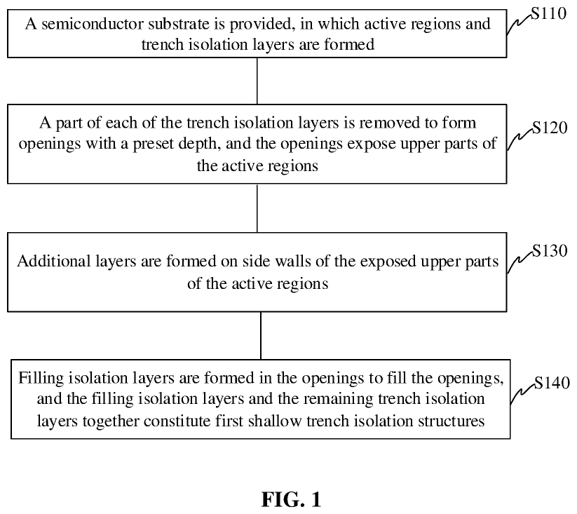

Referring to FIG. 1, the embodiments of this disclosure provide a manufacturing method of a semiconductor structure, and the method includes the following operations.

At S110, a semiconductor substrate 100 is provided, and active areas and trench isolation layers are formed in the semiconductor substrate;

At S120, a part of each of the trench isolation layers are removed to form openings 170 with a preset depth, and the upper parts of the active areas 150 are exposed through the openings 170.

At S130, additional layers 180 are formed on the surfaces of the side walls of the exposed upper parts of the active areas 150.

At S140, filling isolation layers 190 are formed in the openings 170 to fill the openings 170, the filling isolation layers 190 and the remaining trench isolation layers together constitute first shallow trench isolation structures 130.

It can be understood that by forming the additional layers 180 on the side walls of the upper parts of the active areas 150, the width of the tops of the active areas 150 can be effectively increased without increasing the whole size of the active areas 150, so that after storage node contact structures are formed, the contact area between a storage node contact structure and an active area 150 can be increased, so as to solve the problem that the storage node contact structures are open or the storage node contact structures have higher resistance due to too small size of the tops of the active areas 150. In addition, it is even possible to reduce the limitation of the etching process on the depth of shallow trenches by appropriately reducing the width of the active areas 150 to form deeper shallow trenches, thereby further improving the performance of the semiconductor structure.

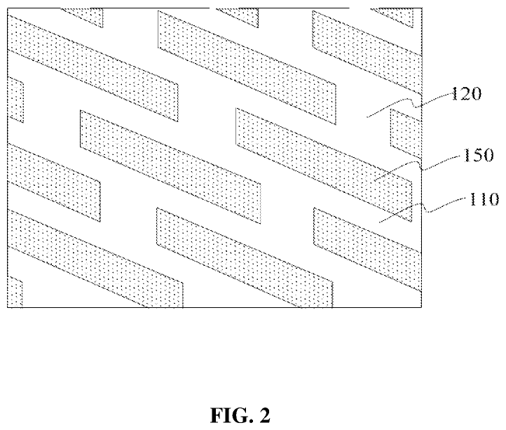

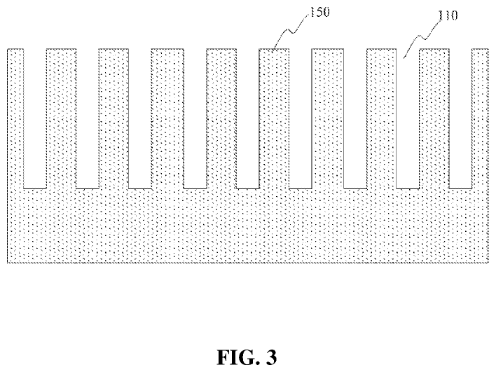

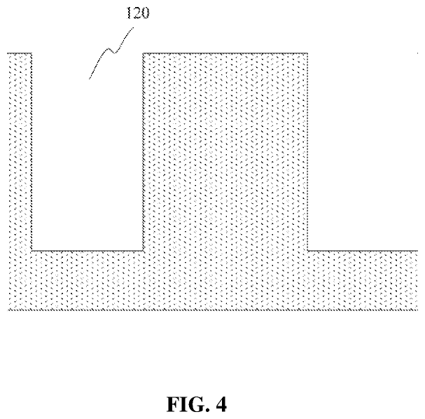

The semiconductor substrate 100 includes storage unit array regions and peripheral circuit regions, and the peripheral circuit regions are located at the periphery of the storage unit array regions. Referring to FIG. 2, FIG. 3 and FIG. 4, FIG. 2 is a top view after shallow trenches are formed, FIG. 3 is a schematic cross-sectional structural view of a storage unit array region, and FIG. 4 is a schematic cross-sectional structural view of a peripheral circuit region.

In this embodiment, the semiconductor substrate 100 includes a silicon substrate, an epitaxial silicon substrate, a silicon germanium substrate, a silicon carbide substrate, or a silicon-coated insulating substrate, but is not limited thereto. Those skilled in the art can select the type of the semiconductor substrate 100 according to a semiconductor structure formed on the semiconductor substrate 100, so that the type of the semiconductor substrate 100 should not limit the protection scope of this disclosure. In this embodiment, the semiconductor substrate 100 is a P-type crystalline silicon substrate.

In this embodiment, first shallow trenches 110 and second shallow trenches 120 are formed on the semiconductor substrate 100, and a plurality of active areas 150 staggered in parallel are defined by the first shallow trenches 110 and the second shallow trenches 120. The first shallow trenches 110 are located in the storage unit array regions, and the second shallow trenches 120 are located in the peripheral circuit regions. The width of a first shallow trench 110 may be less than a width of the second shallow trench 120, and the depth of the first shallow trench 110 may be less than the depth of the second shallow trench 120. The first shallow trenches 110 are filled with an insulating material to form first shallow trench isolation structures 130, and the second shallow trenches 120 are filled with an insulating material to form second shallow trench isolation structures 140.

In one of the embodiments, forming active areas 150 and trench isolation layers are formed in the semiconductor substrate 100 includes the following operations.

An ion implantation region is formed in the semiconductor substrate 100.

Shallow trenches are formed in the ion implantation region, and the shallow trenches isolate a couple of the active areas.

A first insulating material layer 131 is formed, and the first insulating material layer 131 covers the surfaces of the shallow trenches to form the trench isolation layers.

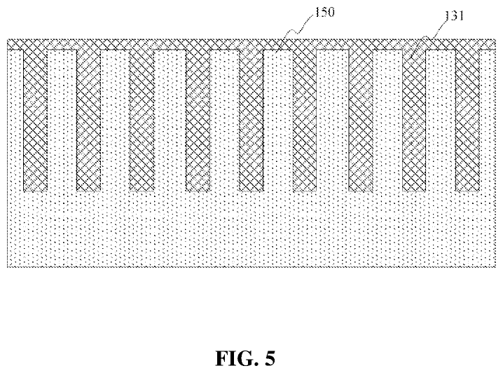

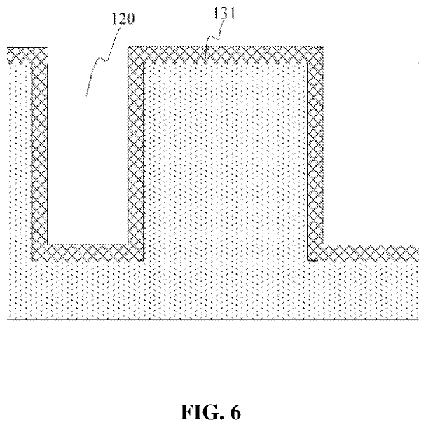

Referring to FIG. 5 and FIG. 6, FIG. 5 and FIG. 6 are respectively a schematic cross-sectional structural view of a storage unit array region and a schematic cross-sectional structural view of a peripheral circuit region after the first insulating material layer 131 is formed. In this embodiment, a layer of photoresist is coated on the surface of the semiconductor substrate 100 by a spin coating process to form a photoresist layer, and then, the photoresist layer is irradiated through a photomask by means of a laser device to expose the photoresist layer so as to cause a chemical reaction of the photoresist in the exposed region. Then, the photoresist in the exposed region (the photoresist layer is a positive photoresist layer) or the photoresist in an unexposed region (the photoresist layer is a negative photoresist layer) is removed by dissolution with a development technology, and patterns on the photomask are transferred to the photoresist layer to form target patterns that define the first shallow trenches 110. Then, the semiconductor substrate 100 is etched by taking the patterned photoresist layer as a mask layer to form the first shallow trenches 110. Finally, a silicon oxide material is deposited by a deposition process to form the first insulating material layer 131. The deposition process may include chemical vapor deposition (CVD), low pressure CVD (LPCVD), plasma enhanced CVD (PECVD), atomic layer deposition (ALD), and plasma enhanced ALD (PEALD).

It can be understood that the first shallow trenches 110 and the second shallow trenches 120 may be formed simultaneously. The manufacturing process of the second shallow trenches 120 will not be described in detail herein. In addition, the formed first insulating material layer 131 also covers the semiconductor substrate 100 in the peripheral circuit regions and the surfaces of the second shallow trenches 120.

In one of the embodiments, after the first insulating material layer 131 is formed and before the openings are formed, the manufacturing method further includes the following operations.

A second insulating material layer 132 is formed, and the second insulating material layer 132 covers the surface of the first insulating material layer 131.

Third insulating material layers 141 are formed to fill the second shallow trenches, and the first insulating material layer 131, the second insulating material layer 132 and the third insulating material layers 141 in the second shallow trenches 120 together constitute second shallow trench isolation structures 140.

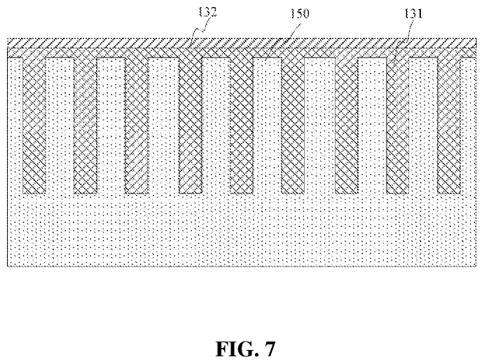

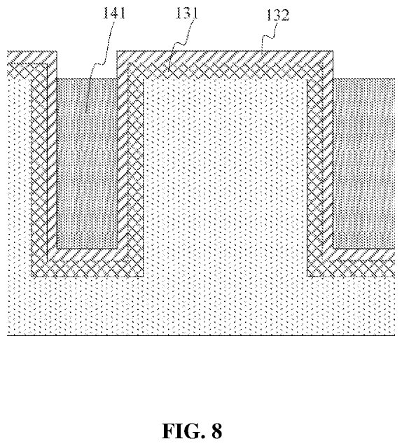

Referring to FIG. 7 and FIG. 8, FIG. 7 and FIG. 8 are respectively a schematic cross-sectional structural view of a storage unit array region and a schematic cross-sectional structural view of a peripheral circuit region after third insulating material layers 141 are formed. In this embodiment, firstly, a silicon nitride material is deposited by a deposition process to form the second insulating material layer 132, and the second insulating material layer 132 covers the surface of the first insulating material layer 131. Then, a silicon oxide material is deposited by a deposition process to form a silicon oxide material layer covering the second insulating material layer 132 and filling the second shallow trenches 120. Finally, the silicon oxide material layer is etched by an etching process, only the silicon oxide material in the second shallow trenches 120 is retained to form the third insulating material layers 141, and the tops of the third insulating material layers 141 are flush with the tops of the active areas 150. In addition, in the operations of forming the third insulating material layers 141, firstly, a part of the silicon oxide material may be removed by a chemical polishing process, and then, the silicon oxide material layer is etched by an etching process to form the third insulating material layers 141.

In one of the embodiments, the operation that a part of each of the trench isolation layers are removed to form openings 170 with a preset depth includes the following operations.

A patterned mask layer is formed on the surface of the substrate.

The second insulating material layer 132 and the first insulating material layer 131 with a preset depth in the storage unit array regions are removed based on the patterned mask layer to form the openings 170.

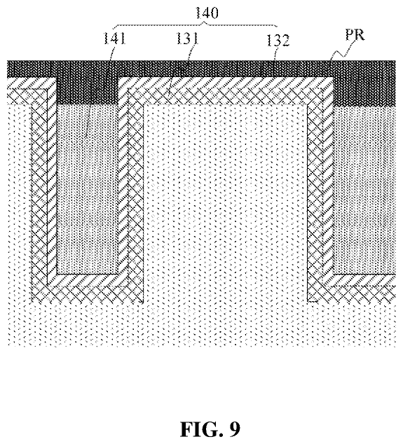

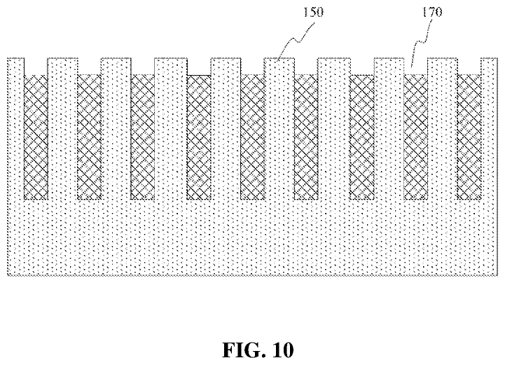

Referring to FIG. 9, after the trench isolation layers are formed, the semiconductor substrate 100 is coated with a photoresist to form the photoresist layer, and the photoresist layer is patterned by a lithography process to form a patterned mask layer covering the peripheral circuit region. Then, the second insulating material layer 132 and the first insulating material layer 131 with a preset depth in the storage unit array regions are removed based on the patterned mask layer. Finally, the patterned mask layer is removed to form the openings 170, referring to FIG. 10.

In one of the embodiments, the preset depth ranges from 5 nm to 100 nm.

It can be understood that when the depth of the openings 170 ranges from 5 nm to 100 nm, the contact area between the additional layers 180 and the side walls of the active areas 150 can be increased to prevent the additional layers 180 from breaking or falling off from the side walls of the active areas 150 due to the self-gravity. In one embodiment, the depth of the openings 170 is set to be 30 nm to 80 nm.

In one of the embodiments, forming additional layers 180 on the surfaces of the side walls of the exposed upper parts of the active areas 150 includes the following operations.

A polysilicon material layer covering the surfaces of the active areas 150 is formed by an epitaxial growth process.

The polysilicon material layer on the top surfaces of the active areas 150 is removed, the polysilicon material layer on the side walls of the exposed upper parts of the active areas is retained as the additional layers 180, and the additional layers 180 cover the side walls of the upper parts of the active areas 150.

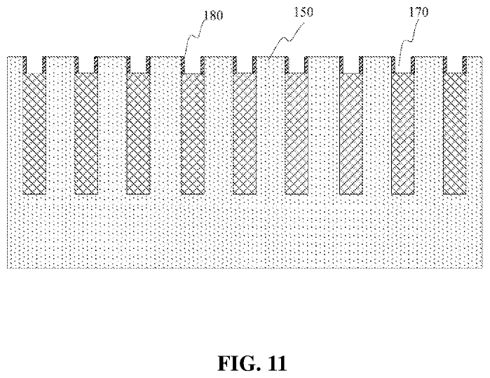

Referring to FIG. 11, in this embodiment, the operations of forming additional layers 180 on the surfaces of the side walls of the exposed upper parts of the active areas 150 specifically includes that: after the openings 170 are formed, an epitaxial growth process is used to grow polysilicon on the surfaces of the exposed active areas 150 to form a polysilicon material layer covering the surfaces of the active areas 150. The grown polysilicon material layer may have the same characteristics as the silicon material of the active areas 150, or may have different conductivity characteristics from the silicon material of the active areas 150. Then, the polysilicon material layer on the top surfaces of the active areas 150 is removed by an etching process to form the additional layers 180 coating the surfaces of the side walls of the exposed upper parts of the active areas 150. In addition, the additional layers 180 may be formed by generating single crystal silicon and etching the single crystal silicon, or the additional layers 180 may be formed by depositing conductive materials such as titanium nitride and etching the conductive materials. This embodiment does not limit the method of forming the additional layers 180.

In one of the embodiments, the thickness of the additional layers 180 ranges from 5 Å to 50 Å.

It can be understood that if the additional layers 180 are too small, the contact area between the storage node contact structures and the active areas cannot be effectively increased. If the thickness of the additional layers 180 is larger, the isolation effect of the first shallow trench isolation structures 130 will be reduced, resulting in increase in dark current. In this embodiment, the thickness of the additional layers 180 is controlled within the range of 5 Å to 50 Å, which can effectively increase the contact area between the storage node contact structures and the active areas, and will not cause the isolation effect of the first shallow trench isolation structures 130 to be significantly reduced.

In one of the embodiments, forming the filling isolation layers 190 includes the following operations.

Filling isolation material layers are deposited to fill the openings 170 and at least cover the tops of the active areas 150, and the thickness of the filling isolation material layers above the active areas 150 is the same as the thickness of the second insulating material layer 132.

The filling isolation material layers are polished by a chemical mechanical polishing process to expose the tops of the active areas 150, and the isolation material layers in the openings are retained as the filling isolation layers 190.

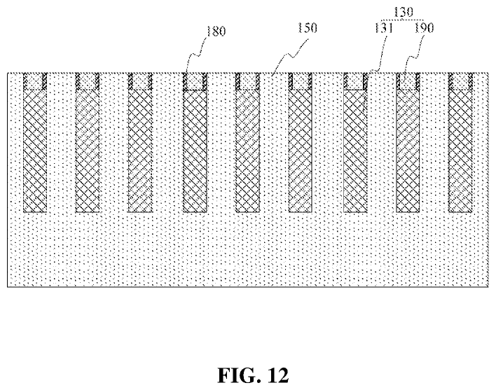

Referring to FIG. 12, in this embodiment, the operations of forming the filling isolation layers 190 specifically includes the following.

Firstly, a silicon oxide material is deposited by a deposition process to form filling isolation material layers, the filling isolation material layers fill the openings 170 and at least cover the tops of the active areas 150, and the thickness of the filling isolation material layers above the active areas 150 is equal to the thickness of the second insulating material layer 132. Then, the silicon oxide material above the active areas 150 is removed by a chemical mechanical polishing process, an etching process or a combination of the chemical mechanical polishing process and the etching process, and the isolation material layers in the openings are retained as the filling isolation layers 190. In addition, the thickness of the filling isolation material layer above the active areas 150 is equal to the thickness of the second insulating material layer 132. That is, before etching back, the tops of the filling isolation material layers are flush with the top of the second insulating material layer 132. Then, the filling isolation layers 190 are etched back to ensure that the tops of the filling isolation layers 190 are flush with the tops of the active areas 150. Subsequently, after the second insulating material layer 132 on the top of the semiconductor in the peripheral circuit regions is removed, the surface of the semiconductor structure may be relatively flat.

The embodiments of this disclosure further provide a semiconductor structure, including a semiconductor substrate 100 and additional layers 180, referring to FIG. 12.

First shallow trench isolation structures 130 and active areas 150 are formed in the semiconductor substrate 100.

The additional layers 180 coat the surfaces of the side walls of the upper parts of the active areas 150.

In this embodiment, by coating the surfaces of the side walls of the upper parts of the active areas 150 with the additional layers 180, the width of the tops of the active areas 150 can be effectively increased without increasing the whole size of the active areas 150, so that after storage node contact structures are formed, the contact area between a storage node contact structure and an active area 150 can be increased, so as to solve the problem that the storage node contact structures are open or the storage node contact structures have higher resistance due to too small size of the tops of the active areas 150. In addition, it is even possible to reduce the limitation of the etching process on the depth of shallow trenches by appropriately reducing the width of the active areas 150 to form deeper shallow trenches, thereby further improving the performance of the semiconductor structure.

In this embodiment, the semiconductor substrate 100 includes a silicon substrate, an epitaxial silicon substrate, a silicon germanium substrate, a silicon carbide substrate, or a silicon-coated insulating substrate, but is not limited thereto. Those skilled in the art can select the type of the semiconductor substrate according to a semiconductor structure formed on the semiconductor substrate 100, so that the type of the semiconductor substrate should not limit the protection scope of this disclosure.

In one of the embodiments, the thickness of the additional layers 180 ranges from 5 Å to 50 Å, and the height of the additional layers 180 ranges from 5 nm to 100 nm.

It can be understood that if the additional layers 180 are too small, the contact area between the storage node contact structures and the active areas cannot be effectively increased. If the thickness of the additional layers 180 is larger, the isolation effect of the first shallow trench isolation structures 130 will be reduced, resulting in increase in dark current. In this embodiment, the thickness of the additional layers 180 is controlled within the range of 5 Å to 50 Å, which can effectively increase the contact area between the storage node contact structures and the active areas, and will not cause the isolation effect of the first shallow trench isolation structures 130 to be significantly reduced. In addition, when the height of the additional layers 180 ranges from 5 nm to 100 nm, the contact area between the additional layers 180 and the side walls of the active areas 150 can be increased to prevent the additional layers 180 from breaking due to the self-gravity or falling off from the side walls of the active areas 150. In one embodiment, the depth of the openings 170 is set to be 30 nm to 80 nm.

In one of the embodiments, the additional layer 180 includes a polysilicon material layer.

In this embodiment, firstly, the upper parts of the active areas 150 are exposed, and then, an epitaxial growth process is used to grow polysilicon on the surfaces of the exposed active areas 150 to form a polysilicon material layer covering the surfaces of the active areas 150. The grown polysilicon material layer may have the same characteristics as the silicon material of the active areas 150, or may have different conductivity characteristics from the silicon material of the active areas. Then, the polysilicon material layer on the tops of the active areas 150 is removed by an etching process to form the polysilicon layer coating the surfaces of the side walls of the exposed upper parts of the active areas 150.

In one of the embodiments, the semiconductor substrate 100 includes storage unit array regions and peripheral circuit regions, the first shallow trench isolation structures 130 are located in the storage unit array regions, and the second shallow trench isolation structures 140 are located in the peripheral circuit regions.

In this embodiment, first shallow trenches 110 and second shallow trenches 120 are formed on the semiconductor substrate 100, and a plurality of active areas 150 staggered in parallel are defined by the first shallow trenches 110 and the second shallow trenches 120. The first shallow trenches 110 are located in the storage unit array regions, the second shallow trenches 120 are located in the peripheral circuit regions, and the width of the first shallow trenches 110 is less than the width of the second shallow trenches 120. The first shallow trench isolation structures 130 are formed in the first shallow trenches 110, and the second shallow trench isolation structures 140 are formed in the second shallow trenches 120.

It can be understood that the first shallow trenches 110 and the second shallow trenches 120 may be formed simultaneously. The specific forming process includes that: a layer of photoresist is coated on the surface of the semiconductor substrate 100 by a spin coating process to form a photoresist layer, and then, the photoresist layer is irradiated through a photomask by means of a laser device to cause a chemical reaction of the photoresist in the exposed region. Then, the photoresist in the exposed region (the photoresist layer is a positive photoresist layer) or the photoresist in an unexposed region (the photoresist layer is a negative photoresist layer) is removed by dissolution through a development technology, and patterns on the photomask are transferred to the photoresist layer to form target patterns for defining the first shallow trenches 110 and the second shallow trenches 120. Then, the semiconductor substrate 100 is etched by taking the patterned photoresist layer as a mask layer to form the first shallow trenches 110 and the second shallow trenches 120.

In one of the embodiments, the first shallow trench isolation structures 130 include trench isolation layers and filling isolation layers 190.

The trench isolation layers are located between adjacent active areas 150.

The filling isolation layers 190 are located on the upper surfaces of the trench isolation layers and located between the additional layers 180 that are located between adjacent active areas 150.

In this embodiment, the silicon oxide material is deposited by a deposition process to form the first insulating material layer 131. In addition, the formed first insulating material layer 131 also covers the semiconductor substrate 100 in the peripheral circuit regions and the surfaces of the second shallow trenches 120. However, since the second shallow trenches 120 are relatively wide, the first insulating material layer 131 cannot fill the second shallow trenches 120. Subsequently, the silicon nitride material is deposited by a deposition process to form the second insulating material layer 132, and the second insulating material layer 132 covers the surface of the first insulating material layer 131. Then, the silicon oxide material is deposited again by a deposition process to form a silicon oxide material layer covering the second insulating material layer 132 and filling the second shallow trenches 120. Finally, the silicon oxide material layer is etched by an etching process, only the silicon oxide material in the second shallow trenches 120 is retained to form the third insulating material layers 141, and the tops of the third insulating material layers 141 are flush with the tops of the active areas 150. The first insulating material layer 131, the second insulating material layer 132 and the third insulating material layers 141 in the second shallow trenches 120 together constitute the second shallow trench isolation structures 140.

In conclusion, in this disclosure, by forming the additional layers 180 on the side walls of the upper parts of the active areas 150, the width of the tops of the active areas 150 can be effectively increased without increasing the whole size of the active areas 150, so that after storage node contact structures are formed, the contact area between a storage node contact structure and an active area 150 can be increased, so as to solve the problem that the storage node contact structures are open or the storage node contact structures have higher resistance due to too small size of the tops of the active areas 150. In addition, it is even possible to reduce the limitation of the etching process on the depth of shallow trenches by appropriately reducing the width of the active areas 150 to form deeper shallow trenches, thereby further improving the quality of the semiconductor structure.

The technical features of the above embodiments may be combined arbitrarily. In order to simplify the description, all possible combinations of the technical features in the above embodiments are not completely described. However, as long as there is no conflict between these technical features, they should be considered to be within the scope of this specification.

The foregoing embodiments represent only a few implementation modes of this disclosure, and the descriptions are relatively specific and detailed, but should not be construed as limiting the patent scope of this disclosure. It should be noted that those of ordinary skill in the art may further make variations and improvements without departing from the conception of this disclosure, and these variations and improvements all fall within the protection scope of this disclosure. Therefore, the patent protection scope of this disclosure should be subject to the appended claims.

1. A method for manufacturing a semiconductor structure, comprising:
providing a semiconductor substrate, a plurality of active areas and trench isolation layers being provided in the semiconductor substrate;
removing a part of each of the trench isolation layers to form a plurality of openings with a preset depth, the openings exposing upper parts of the active areas;
forming additional layers on side walls of the exposed upper parts of the active areas; and
forming filling isolation layers in the openings to fill the openings, the filling isolation layers and the remaining trench isolation layers together constituting first shallow trench isolation structures.

2. The method of claim 1, wherein forming the additional layers on the side walls of the exposed upper parts of the plurality of active areas comprises:
forming a polysilicon material layer covering surfaces of the active areas by an epitaxial growth process; and
removing the polysilicon material layer on top surfaces of the active areas, retaining the polysilicon material layer on the side walls of the exposed upper parts of the active areas as the additional layers, the additional layers covering the side walls of the upper parts of the active areas.

3. The method of claim 1, wherein a thickness of the additional layers ranges from 5 Å to 50 Å.

4. The method of claim 1, wherein the preset depth ranges from 5 nm to 100 nm.

5. The method of claim 1, wherein forming the plurality of active areas and the trench isolation layer in the semiconductor substrate comprises:
forming a plurality of shallow trenches in the semiconductor substrate, the plurality of shallow trenches isolating the plurality of the active areas; and
forming a first insulating material layer, the first insulating material layer covering surfaces of the shallow trenches to form the trench isolation layers.

6. The method of claim 5, wherein the semiconductor substrate has a storage unit array region and a peripheral circuit region, and the shallow trenches comprise a plurality of first shallow trenches located in the storage unit array region and a plurality of second shallow trenches located in the peripheral circuit region; the first shallow trenches are formed at the same time as the second shallow trenches are formed; and the first insulating material layer covers the surfaces of the first shallow trenches and the second shallow trenches as well.

7. The method of claim 6, further comprising: after forming the first insulating material layer and before forming the plurality of openings,
forming a second insulating material layer, the second insulating material layer covering the surface of the first insulating material layer; and
forming a third insulating material layer to fill the second shallow trenches, wherein the first insulating material layer, the second insulating material layer and the third insulating material layer in the second shallow trenches together constitute second shallow trench isolation structures.

8. The method of claim 7, wherein removing a part of each of the trench isolation layers to form the plurality of openings with a preset depth comprises:
forming a patterned mask layer on the surface of the semiconductor substrate; and
removing the second insulating material layer and the first insulating material layer with the preset depth in the storage unit array region based on the patterned mask layer to form the openings.

9. The method of claim 7, wherein forming the filling isolation layers comprises:
depositing a filling isolation material layer to fill the openings and at least cover tops of the active areas, wherein a thickness of the filling isolation material layer above the active areas is the same as the thickness of the second insulating material layer; and
polishing the filling isolation material layer by a chemical mechanical polishing process to expose the tops of the active areas, retaining the filling isolation material layer in the openings as the filling isolation layers.

10. A semiconductor structure, comprising:
a semiconductor substrate in which a plurality of first shallow trench isolation structures and a plurality of active areas are provided; and
additional layers coating on side walls of upper parts of the active areas.

11. The semiconductor structure of claim 10, wherein a thickness of the additional layers ranges from 5 Å to 50 Å, and a height of the additional layers ranges from 5 nm to 100 nm.

12. The semiconductor structure of claim 10, wherein a material of the additional layers is polysilicon.

13. The semiconductor structure of claim 10, wherein the plurality of first shallow trench isolation structures comprise:
trench isolation layers located between adjacent ones of the active areas; and
filling isolation layers located on upper surfaces of the trench isolation layers, and located between the additional layers which are located between the adjacent ones of the active areas.

14. The semiconductor structure of claim 10, wherein the semiconductor substrate comprises a storage unit array region and a peripheral circuit region, the plurality of first shallow trench isolation structures are located in the storage unit array region, and a plurality of second shallow trench isolation structures are located in the peripheral circuit region.
